(19) United States
(12) Patent Application Publication
(10) Pub. No.: US 2025/0149496 A1
(43) Pub. Date: May 8, 2025

(54) SEMICONDUCTOR MODULE AND METHOD OF MANUFACTURING A SEMICONDUCTOR MODULE

(71) Applicant: FUJI ELECTRIC CO., LTD., Kawasaki-shi (JP)

(72) Inventors: Ryoichi KATO, Matsumoto-city (JP); Naoyuki KANAI, Matsumoto-city (JP); Yuichiro HINATA, Matsumoto-city (JP)

(73) Assignee: FUJI ELECTRIC CO., LTD., Kawasaki-shi (JP)

(21) Appl. No.: 18/901,928

(22) Filed: Sep. 30, 2024

(30) Foreign Application Priority Data
Nov. 7, 2023 (JP) 2023-189875

(51) Int. Cl. H01L 23/00; H01L 23/31; H01L 23/498

(52) U.S. Cl. CPC H01L 24/37; H01L 23/3107; H01L 24/40; H01L 24/84; H01L 23/49822; H01L 2224/37011; H01L 2224/37012; H01L 2224/40227; H01L 2224/40475

(57) ABSTRACT

A semiconductor module, including: a stacked substrate; a semiconductor device mounted on the stacked substrate; a lead frame electrically connected to the semiconductor device; and an encapsulation resin that encapsulates the semiconductor device, the lead frame, and the stacked substrate. The lead frame has a bonding portion bonded to the semiconductor device, the bonding portion having a plurality of recesses provided thereon.

### CROSS REFERENCE TO RELATED APPLICATIONS

This application is based upon and claims the benefit of priority of the prior Japanese Patent Application No. 2023-189875, filed on Nov. 7, 2023, the entire contents of which are incorporated herein by reference.

### BACKGROUND OF THE INVENTION

### 1. Field of the Invention

Embodiments of the disclosure relate to a semiconductor module and a method of manufacturing a semiconductor module.

### 2. Description of the Related Art

In a known semiconductor device, before a wire is bonded to a lead portion, a roughened area is formed on the lead part by laser irradiation, thereby surrounding a bonding portion of the wire by an area having high adhesion to a mold resin, whereby breakage of the wire caused by stress is suppressed (for example, refer to Japanese Laid-Open Patent Publication No. 2018-157023).

### SUMMARY OF THE INVENTION

According to an embodiment of the present disclosure, a semiconductor module includes: a stacked substrate; a semiconductor device mounted on the stacked substrate; a lead frame electrically connected to the semiconductor device; and an encapsulation resin that encapsulates the semiconductor device, the lead frame, and the stacked substrate. The lead frame has a bonding portion bonded to the semiconductor device, the bonding portion having a plurality of recesses provided thereon.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a configuration of a semiconductor module 50 according to an embodiment.

FIG. 2 is a cross-sectional view depicting a structure of a bonding portion of a lead frame and semiconductor chips of the semiconductor module according to the embodiment.

FIG. 3 is a plan view of a structure of the lead frame of the semiconductor module according to the embodiment.

FIG. 4 is a top view depicting the structure of the lead frame of the semiconductor module according to the embodiment.

FIG. 5 is a perspective view depicting the structure of the lead frame of the semiconductor module according to the embodiment.

FIG. 6 is a graph depicting a relationship between deformation of a top electrode and percentage of recess volume of the semiconductor module according to the embodiment.

FIG. 7 is a graph depicting a relationship between longitudinal positions where recesses are provided and deformation of the top electrode of the semiconductor module according to the embodiment.

FIG. 8 is a graph indicating a relationship between the longitudinal positions where the recesses are provided and deformation of the top electrode of the semiconductor module according to the embodiment.

FIG. 9 is a graph indicating a relationship between the longitudinal positions where the recesses are provided and deformation of the top electrode of the semiconductor module according to the embodiment.

FIG. 10 is a graph depicting a relationship between the longitudinal positions where the recesses are provided and deformation of the top electrode of the semiconductor module according to the embodiment.

FIG. 11 is a graph depicting a relationship between the longitudinal positions where the recesses are provided and deformation of the top electrode of the semiconductor module according to the embodiment.

FIG. 12 is a graph depicting distortion of the top electrode due to thermal stress of the conventional semiconductor module.

FIG. 13 is a flowchart depicting a method of manufacturing the semiconductor module according to the embodiment.

### DETAILED DESCRIPTION OF THE INVENTION

First, problems associated with the conventional techniques are discussed. In a conventional semiconductor module, due to thermal stress, problems arise such as peeling between a lead frame and an encapsulation resin, cracking of electrodes of a semiconductor device, and peeling between the electrodes and bonding materials such as solder.

A semiconductor module according to the present disclosure has the following features. A semiconductor module includes a stacked substrate having a semiconductor device (also referred to as “semiconductor chip”) mounted thereon; a lead frame electrically connected to the semiconductor device; and an encapsulation resin that encapsulates encapsulation members including the semiconductor device, the lead frame, and the stacked substrate, where the lead frame has a bonding portion bonded to the semiconductor device and a plurality of recesses provided on the bonding portion.

According to the disclosure above, the plurality of recesses is provided on the bonding portion of the lead frame, whereby thermal stress applied to the top electrode is reduced, whereby deformation of the top electrode may be reduced and the reliability of the semiconductor module may be enhanced.

Further, in the semiconductor module according to the present disclosure, each of the plurality of recesses has a pore size in a range of 0.05 mm to 0.4 mm and a depth in a range of 0.1 mm to 0.45 mm.

Further, in the semiconductor module according to the present disclosure, a percentage of a total volume of the plurality of recesses relative to a volume of the bonding portion is 5% or more.

According to the disclosure above, a maximum distortion of the top electrode may be reduced by 4%.

Further, in the semiconductor module according to the present disclosure, the plurality of recesses is provided in a single row in a lateral direction of the lead frame, and a position of each of the plurality of recesses is a position where a rate D/L is 60% or less, where “L” is a length of the bonding portion and “D” is a length from a base of the lead frame to a center of the each of the plurality of recesses. As depicted in FIG. 2, the base is a boundary portion between a bonding portion 31 and a curved portion 32 of the lead frame.

According to the disclosure above, deformation of the top electrode may be reduced by 3% or more and the reliability may be enhanced by 30% or more.

Further, in the semiconductor module according to the present disclosure, the position of each of the plurality of recesses is a position where the rate D/L is in a range of 10% to 40%.

According to the disclosure above, deformation of the top electrode is reduced by 3.5% or more and the reliability is enhanced by 40% or more.

Further, in the semiconductor module according to the present disclosure, the plurality of recesses is disposed in a plurality of rows at positions up to the rate D/L in a lateral direction of the lead frame, where “L” is the length of the bonding portion and “D” is the length from the base of the lead frame to a center of the each of the plurality of recesses, and the rate D/L is in a range of 5% to 20%.

According to the disclosure above, deformation of the top electrode may be reduced by 3% or more and the reliability may be enhanced by 40% or more.

Further, in the semiconductor module according to the present disclosure, the rate D/L is in a range of 20% to 60%.

According to the disclosure above, deformation of the top electrode may be reduced by 4% or more and the reliability may be enhanced by 50% or more.

A method of manufacturing a semiconductor module according to the present disclosure has the following features. The method includes a first process of bonding a semiconductor device on a stacked substrate; a second process of bonding the semiconductor device and a lead frame having a plurality of recesses; a third process of encapsulating the stacked substrate with a resin; and a fourth process of curing the resin. The method further includes a process of forming the plurality of recess in a bonding portion of the lead frame before bonding the semiconductor device and the lead frame, the bonding portion of the lead frame being bonded to the semiconductor device.

Here, problems associated with the conventional semiconductor module are discussed. The conventional semiconductor module includes a semiconductor chip, a stacked substrate, a case, a heat dissipation base, and a lead frame. The semiconductor chip is a power semiconductor chip such as a metal-oxide-semiconductor field effect transistor (MOSFET), an insulated gate bipolar transistor (IGBT), or a diode bonded on the stacked substrate by bonding layer such as solder. The stacked substrate refers to an insulated substrate such as a ceramic substrate having, at a front surface thereof, a first conductive plate containing, for example, copper and at a back surface, a second conductive plate containing, for example, copper. The stacked substrate is bonded to the heat dissipating base by a bonding layer such as a solder. Further, in an instance of a MOSFET, a source electrode pad is formed as a power terminal electrode pad (current supply terminal) at a surface of the semiconductor chip. Further, a conductive connecting member such as a lead frame or a metal wire is disposed as a lead terminal from the power terminal electrode pad. The power terminal electrode pad (top electrode) of the semiconductor chip and the lead frame are bonded by a bonding layer such as a solder. The case is mounted to the semiconductor module and a cover through which metal terminals penetrate and protrude externally is attached. The case is filled with the encapsulation resin, which insulates and protects the stacked substrate and the semiconductor chip on the substrate.

FIG. 12 is a graph depicting distortion of the top electrode due to thermal stress of the conventional semiconductor module. In FIG. 12, a horizontal axis indicates distance from an end of a bonding layer 27 on a surface of the semiconductor chip in units of mm. A vertical axis indicates distortion of the power terminal electrode pad (top electrode) of the semiconductor chip in units of percent (%). FIG. 12 depicts results of thermal stress analysis performed by a finite element method (FEM). In FIG. 12, “L11” is portion (bonding portion) where a lead frame and the top electrode are bonded to each other, the bonding portion having a length of about 3.0 mm. Further, “L12” corresponds to a base portion (portion near a curved portion) of the bonding portion of the lead frame. As depicted in FIG. 12, maximum distortion (A11) in the electrode occurs at the base portion of the bonding portion.

As described, the conventional semiconductor module has problems in that due to thermal stress applied to the lead frame, tensile stress further acts in a horizontal direction of the top electrode, whereby deformation of the top electrode occurs, cracks occur in the top electrode, peeling between the top electrode and the bonding material such as solder occurs. A further problem arises in that thermal stress due to power cycling, heat cycling, etc. causes the lead frame and the encapsulation resin to peel.

A semiconductor module and a method of manufacturing a semiconductor module according to the present disclosure is described in detail with reference to the accompanying drawings. However, the present disclosure is not limited by the embodiments described below.

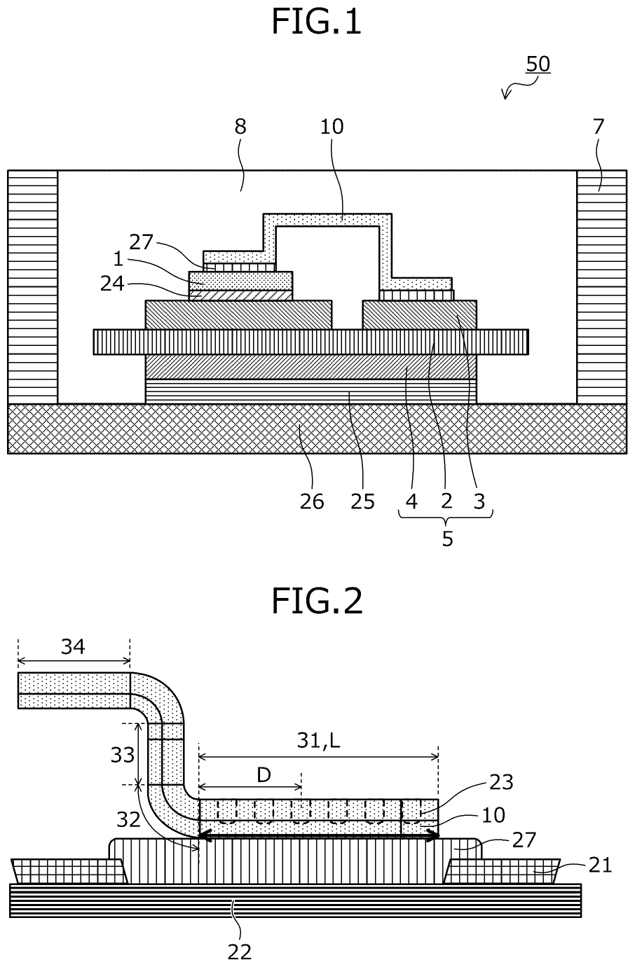

A semiconductor module according to the embodiment and solving the problems above is described. FIG. 1 is a cross-sectional view depicting a configuration of a semiconductor module 50 according to the embodiment. In the semiconductor module 50, a stacked substrate 5 is configured by a first conductive plate 3 containing copper and disposed at a front surface of an insulated substrate 2 and a second conductive plate 4 containing copper and disposed at a back surface of the insulated substrate 2. Multiple semiconductor chips 1 are mounted to a front surface of the first conductive plate 3 of the stacked substrate 5, via a bonding layer 24 containing a solder, a sintered material, or the like. The first conductive plate 3 is formed by a predetermined circuit pattern on the front surface (first main surface) of the insulated substrate 2. The second conductive plate 4 of a back surface of the stacked substrate 5 is bonded to a front surface of a heat dissipation base 26 by the bonding layer 25 containing a solder, a sintered material, etc. The second conductive plate 4 may be a metal foil formed in an entire area of the back surface (second main surface) of the insulated substrate 2.

Metal terminals (not depicted) for external output of signals are bonded in a case 7. Further, a lead frame 10 constituting a conductive connecting member is attached to a front surface (for example, a source electrode pad) of the semiconductor chips 1, via the bonding layer 27. Further, the case 7 is filled with an encapsulation resin 8. The depicted configuration of the semiconductor module 50 is one example and the present disclosure is not limited to this configuration. For example, a module structure that is free of the case 7 is possible.

The semiconductor chips 1 are power chips such as metal oxide semiconductor field effect transistors (MOSFETs), insulated gate bipolar transistors (IGBTs), or Schottky barrier diodes (SBD), and devices may be used that employ a semiconductor substrate containing Si, SiC, GaN, etc. In particular, the present disclosure is effective for SiC chips and GaN chips having large power and a high Young's modulus. The number of the semiconductor chips 1 mounted may be 1 or more than 1. At an upper surface of each of the semiconductor chips 1, a top electrode 22 such as the source electrode pad containing an aluminum alloy is formed.

The stacked substrate 5 may be configured by the insulated substrate 2, the first conductive plate 3 formed in a predetermined shape on the first main surface of the insulated substrate 2, and the second conductive plate 4 formed on the second main surface of the insulated substrate 2. The surface of the first conductive plate 3 and a back surface of each of the semiconductor chips 1 are bonded to each other via a bonding layer 24. A material affording favorable electrical insulation and thermal conductivity may be used as the insulated substrate 2. A material of the insulated substrate 2 may be, for example, Al₂O₃, AlN, SiN, or the like. In particular, for high-voltage applications, while a material that affords both electrical insulation and thermal conductivity is preferable and AlN and SiN may be used, the material is not limited hereto. Copper (Cu) or a Cu alloy, which have favorable processability, may be used as the first conductive plate 3 and the second conductive plate 4. The Cu alloy is an alloy containing 80% or more Cu. Among such conductive plates made of Cu or a Cu alloy, a conductive plate that is not in contact with the semiconductor chips 1 may be referred to as a back copper foil or a back conductive plate. As a method of providing the conductive plate on the insulated substrate 2, a direct bonding method (direct copper bonding) or a brazing method (active metal brazing) may be used. Further, at the surface of the conductive plate, nickel (Ni) plating or the like may be performed and a Ni or a Ni alloy layer may be formed.

The heat dissipation base 26 is, for example, a heat sink that has a substantially rectangular shape in a plan view of the module and contains a metal such as Cu or Al having favorable thermal conductivity and is also referred to as a metal substrate. The surface of the heat dissipation base 26 may be covered by a Ni film or a Ni alloy film, which have an anticorrosion effect. A back surface of the heat dissipation base 26 may be bonded to cooling base portion (not depicted). The heat dissipation base 26 may be bonded to the second conductive plate 4 of the stacked substrate via the bonding layer 25, the heat dissipation base 26 conducts, to a heat dissipation fin part, heat that is generated by the semiconductor chips 1 and transmitted through the stacked substrate 5. The heat dissipation fin part has multiple heat dissipation fins and dissipates the heat conducted from the heat dissipation base 26. The heat dissipation base 26 itself may be a cooling mechanism such as the heat dissipation fin part.

The bonding layer 27, the bonding layer 24, and the bonding layer 25 may be formed using a lead-free solder. For example, without limitation hereto, a Sn—Sb type, a Sn—Cu type, a Sn—Ag type, a Sn—Sb—Ag type, etc. may be used. Further, the bonding layer 27 may be formed using a connecting material containing microscopic metal particles such as a sintered material of silver nanoparticles.

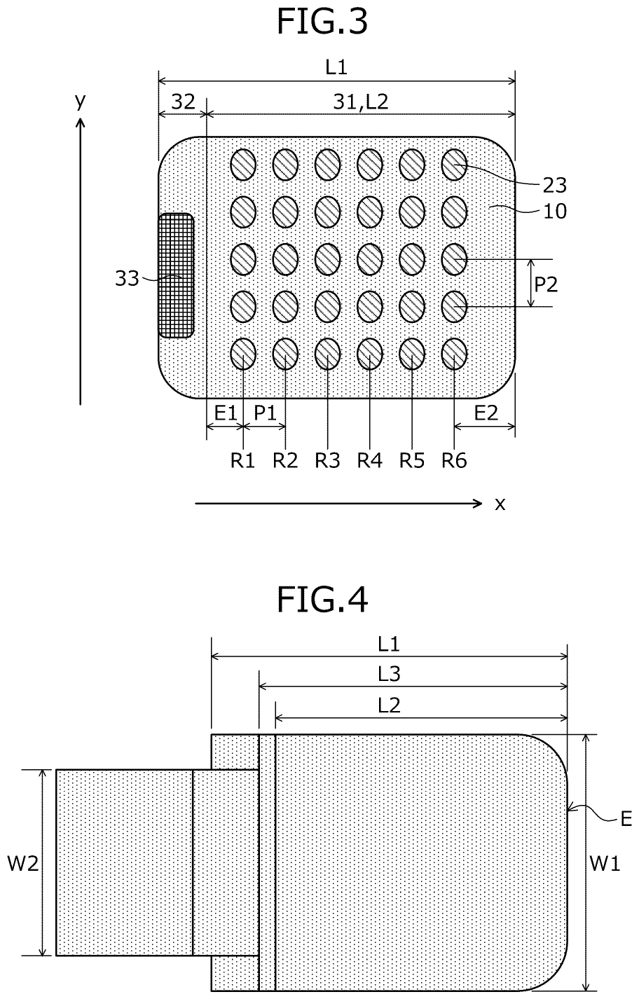

The lead frame 10 is conductive wiring electrically connecting the first conductive plate 3 of the stacked substrate 5, the metal terminals for external signal output (not depicted), etc. via a bonding material such as the bonding layer 27, from the top electrode 22 of the semiconductor chips 1. FIG. 2 is a cross-sectional view depicting a structure of a bonding portion of the lead frame and the semiconductor chips of the semiconductor module according to the embodiment. FIG. 3 is a plan view of a structure of the lead frame of the semiconductor module according to the embodiment.

As depicted in FIG. 2, the lead frame 10 has: a bonding portion 31 bonded to the bonding layer 27 on the top electrode 22 of the semiconductor chips 1, a curved portion 32 connecting the bonding portion 31 and a rising portion 33, the rising portion 33 being provided so as to be apart from the top electrode 22 in a direction substantially orthogonal to the upper surfaces of the semiconductor chips 1, the curved portion 32 connecting the rising portion 33 and a connecting portion 34, the connecting portion 34 being substantially parallel to the upper surfaces of the semiconductor chips 1 and connecting other bonding portions (the first conductive plate 3, the metal terminals for external signal output, etc.). The bonding portion 31 of the lead frame 10 is bonded to the top electrode 22 of the semiconductor chips 1 via a portion of the bonding layer 27 provided in an opening of an insulating protective film 21. The base portion of the lead frame is a portion of the bonding portion 31, near the curved portion.

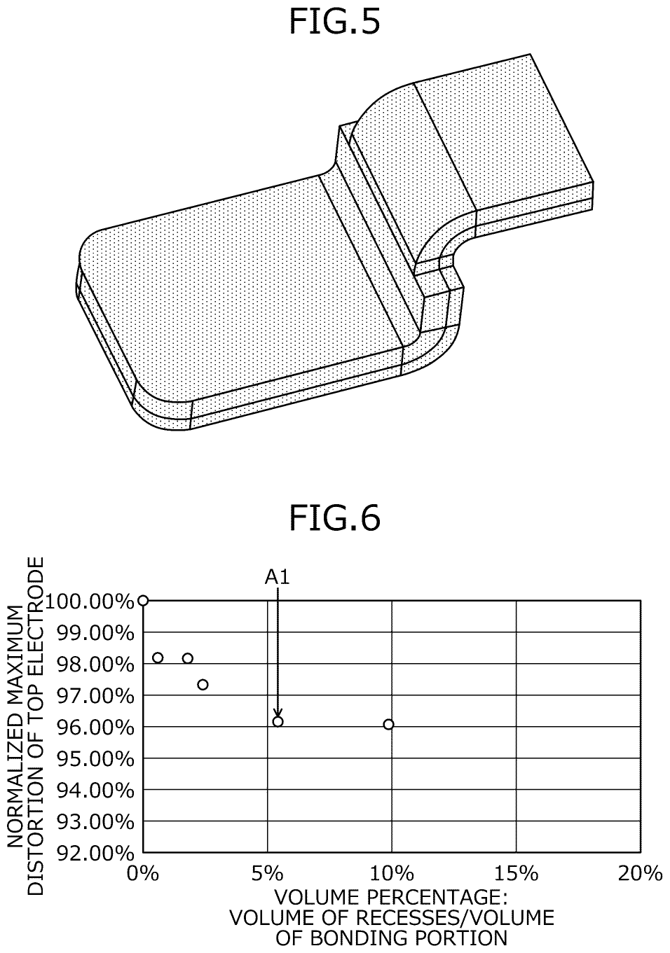

FIG. 4 is a top view depicting the structure of the lead frame of the semiconductor module according to the embodiment. FIG. 5 is a perspective view depicting the structure of the lead frame of the semiconductor module according to the embodiment. For example, a length L1 of the lead frame 10 in a longitudinal direction (x-direction) is 3.5 mm, a length L2 (L) of the bonding portion 31 from an end (the tip) E of the lead frame 10 to the curved portion 32 is 2.8 mm, and a length L3 from the end (the tip) E of the lead frame 10 to the rising portion 33 is 3.1 mm. Further, a width (width of the bonding portion 31) W1 of the lead frame 10 in a lateral direction (y-direction) is 2.7 mm and a width W2 of the connecting portion 34 is 2.0 mm. The structure depicted in FIGS. 4 and 5 is one example and another structure may be adopted in which, for example, the width of the bonding portion 31 and the width of the connecting portion 34 are the same. As depicted in FIGS. 4 and 5, in the rising portion 33, the width on the bonding portion 31 side may be longer than the width on the connecting portion 34 side. The width of the rising portion 33 on the connecting portion 34 side is short, whereby thermal stress applied to the top electrode 22 (base portion of the lead frame 10) may be reduced. The lead frame 10 may have a thickness of 0.5 mm, contain copper, and may be Ni-plated (NiP) after formation of later-described recesses 23.

In the embodiment, as depicted in FIGS. 2 and 3, the recesses 23 are provided in the bonding portion 31. An upper surface of the bonding portion 31 is a first surface thereof opposite a second surface thereof facing the semiconductor chips 1, the first surface being in contact with the encapsulation resin 8. The recesses 23 have a circular shape in a top view and are disposed evenly in dot-like shapes in an entire area of the surface of the bonding portion 31. In addition to a circular shape, the shape of each of the recesses 23 in a top view may be an elliptic shape, a square shape, a rectangular shape, or a rhombus shape. Further, a cross-sectional shape of each of the recesses 23 may be a bulging shape, a hemispherical shape, or a rectangular shape, or a trapezoidal shape, a triangular shape, or a wedge shape in which a tip of each of the recesses 23 is narrowed. Each of the recesses 23, for example, has a pore size in a range of 0.05 mm to 0.4 mm and a depth in a range of 0.1 mm to 0.45 mm. For example, as depicted in FIG. 3, the recesses 23 are formed by press molding, in 6 rows (0.5 mm pitch P1) in the longitudinal direction and 5 rows in the lateral direction (0.46 mm pitch P2). The recesses 23 may be formed by laser processing or the like. Further, of the recesses 23, row R1 closest to the rising portion 33 is apart from an end of the bonding portion 31 closest to the rising portion 33 by a distance E1 (for example, 0.15 mm) and of the recesses 23, row R6 farthest from the rising portion 33 is apart from the end of the bonding portion 31 farthest from the rising portion 33 by a distance E2 (for example, 0.15 mm).

FIG. 6 is a graph depicting a relationship between deformation of the top electrode and percentage of recess volume of the semiconductor module according to the embodiment. FIGS. 2 and 3 depict an instance in which the recesses 23 are provided evenly in an entire area of an upper surface of the bonding layer 27. The upper surface is the surface in contact with the encapsulation resin 8. In FIG. 6, a horizontal axis indicates a ratio of a total volume of the recesses 23 to the volume of the bonding portion 31 of the lead frame 10 (volume percentage:volume of the recesses 23/volume of the bonding portion 31) in units of percent (%). A vertical axis indicates a normalized maximum distortion of the top electrode 22 of the semiconductor chips 1 in units of percent (%). FIG. 6 depicts results of thermal stress analysis by a FEM. In the embodiment as well, similar to the conventional example, maximum distortion occurs in the electrode at the base portion of the bonding portion 31 and the maximum distortion is distortion of the top electrode 22 at the base portion of the bonding portion 31. In FIG. 6, the conventional example in which the recesses 23 are not provided is assumed as 100%.

The volume of the recesses 23 may be changed such that the depth of the recesses 23 is in a range of 0.1 mm to 0.45 mm and the pore size in a range of 0.05 mm to 0.4 mm. The volume of the bonding portion 31 of the lead frame 10 is 3.1 mm×2.7 mm×0.5 mm.

As depicted in FIG. 6, all volume percentages indicate an effect in that by providing the recesses 23, the maximum distortion of the top electrode 22 is reduced independent of the volume percentage. Further, as indicated by Al in FIG. 6, when the volume percentage is 5% or greater, the maximum distortion of the top electrode may be reduced 4%. For example, the volume percentage of 5.4% may be realized by setting the recesses 23 to have a pore size of 0.2 mm and a depth of 0.4 mm. As described, in the embodiment, the recesses 23 are provided in plural in the lead frame 10, particularly, on the bonding portion 31, whereby thermal stress applied to the top electrode 22 is reduced, deformation of the top electrode 22 may be reduced, and the reliability of the semiconductor module 50 may be enhanced.

The case 7 contains a resin and has a lower end that is adhered to a peripheral edge of the heat dissipation base 26. The case 7 forms a substantially rectangular tube shape and surrounds a periphery of the front surface of the heat dissipation base 26. A box shape recess is formed by the front surface of the heat dissipation base 26 constituting a bottom surface and an inner wall of the case 7 constituting sidewalls, the inner wall of the case 7 being orthogonal to the front surface of the heat dissipation base 26. In the recess, wiring member components, the stacked substrate 5, and the semiconductor chips 1 wired by wiring members of the lead frame 10 are housed. A material of the case 7, for example, may be a thermoplastic resin such as polyphenylene sulfide (PPS) and polybutylene terephthalate (PBT), a thermosetting resin such as a phenolic resin, etc. The semiconductor module 50 may be formed by the semiconductor chips 1, the stacked substrate 5, and the encapsulation resin 8, etc. without the case 7.

The encapsulation resin 8 is used for an encapsulation resin layer that encapsulates encapsulation members that are to be encapsulated, the encapsulation resin 8 being provided in contact with the encapsulation members, primarily covering the semiconductor chip 1, the laminated substrate 5, the lead frame 10, and the like. The encapsulation resin 8 may have a thermosetting resin composition and in particular, preferably, may have a thermosetting resin composition having high heat resistance. The thermosetting resin composition contains a thermosetting resin main agent and may optionally contain an inorganic filler, a curing agent, a curing accelerator, and necessary additives. The thermosetting resin composition of the encapsulation resin 8 may or may not contain a fluorinated silane coupling agent, but preferably does not contain a fluorinated silane coupling agent. A reason for this is that the glass transition temperature (Tg) of the encapsulation resin 8 may be reduced.

Examples of the thermosetting resin main agent include epoxy resins, phenolic resins, maleimide resins, and the like. Among these, epoxy resins having at least two or more epoxy groups in one molecule are particularly preferable due to having high dimensional stability, water resistance, chemical resistance, and electrical insulation. In particular, preferably an aliphatic epoxy resin, an alicyclic epoxy resin, or a mixture thereof may be used.

The thermosetting resin composition according to the present embodiment may include an inorganic filler (filler) as an optional constituent. Without limitation hereto, the inorganic filler may be a metal oxide or a metal nitride, and examples include fused silica (fused silicon oxide), silica (silicon oxide), alumina (aluminum oxide), aluminum hydroxide, titania (titanium oxide), zirconia (zirconium oxide), aluminum nitride, talc, clay, mica, glass fiber, and the like. The thermal conductivity of the cured product may be increased and the coefficient of thermal expansion may be reduced by these inorganic fillers. Furthermore, these inorganic fillers may be used alone or in a combination of two or more. Further, these inorganic fillers may be microfillers or nanofillers, and two or more inorganic fillers of different types and/or particle sizes may be used in combination. In terms of adhesion, preferably, the inorganic filler may penetrate inside at least a portion of each of the recesses 23 and an inorganic filler having a large amount of inorganic filler having a small particle size is preferable to an inorganic filler having a particle size larger than the pore size of the recesses 23. In particular, the particle size of the inorganic filler (average particle size) may be, preferably, 5 μm to 100 μm and more preferably, may be from 20 μm to 60 μm. Further, preferably, the thermosetting resin may contain 10% to 20% of an inorganic filler having a particle size in a range of 5 μm to 10 μm, which is smaller than the diameter of each of the recesses 23 in a top view. The particle size of the inorganic filler may be measured using a particle size distribution measuring instrument employing laser scattering.

The thermosetting resin composition may include a curing agent in addition to the thermosetting resin main agent as an optional constituent or in addition to the thermosetting resin main agent and the inorganic filler. As the curing agent, preferably, an acid anhydride curing agent may be used, however, provided the agent reacts with and cures the thermosetting resin main agent, preferably, the epoxy resin main agent, the agent is not particularly limited. Examples of the acid anhydride curing agent include aromatic acid anhydrides, particularly, phthalic anhydride, pyromellitic dianhydride, trimellitic anhydride, and the like. Alternative examples include cyclic aliphatic anhydrides, particularly, tetrahydrophthalic anhydride, methyltetrahydrophthalic anhydride, hexahydrophthalic anhydride, methylhexahydrophthalic anhydride, methylnadicic anhydride, etc., or aliphatic acid anhydrides, particularly, succinic anhydride, polyadipic anhydride, polysebacic anhydride, polyaselaic anhydride, etc. When bisphenol A-type epoxy resin alone or a mixture of bisphenol A epoxy resin and the high-heat-resistant epoxy resin described above is used as the thermosetting resin main agent, it may be preferable not to use a curing agent because the heat resistance is enhanced.

A curing accelerator may be further added to the thermosetting resin composition as an optional constituent. As the curing accelerator, imidazole or a derivative thereof, a tertiary amine, a boric acid ester, a Lewis acid, an organometallic compound, an organoacid metal salt, and the like may be suitably combined.

The thermosetting resin composition may further contain an optional additive to the extent that properties of the thermosetting resin composition are not inhibited. Additives may include, but are not limited to, flame retardants, pigments for coloring resins, plasticizers for improving crack resistance, and silicon elastomers. These optional constituents, and the amounts thereof may be determined suitably by those skilled in the art according to specifications required of the semiconductor device and/or encapsulant.

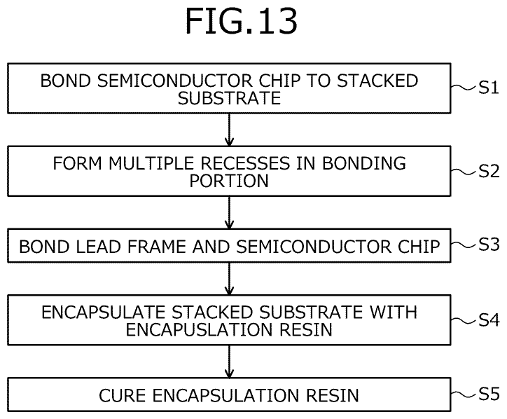

Next, a method of manufacturing a semiconductor module according to the embodiment is described. FIG. 13 is a flowchart depicting the method of manufacturing the semiconductor module according to the embodiment. First, the semiconductor chips 1 are bonded to the stacked substrate 5 by the bonding layer 24 (step S1: first process). The recesses 23 are formed in the lead frame 10, for example, in the bonding portion 31, by press molding, laser processing or the like before the lead frame 10 is bonded (step S2: process of forming multiple recesses).

Thereafter, the lead frame 10 having the recesses 23 and the semiconductor chips 1 are bonded to each other (step S3: second process). Next, stacked substrate 5 is encapsulated with the thermosetting resin composition constituting the encapsulation resin 8 (step S4: third process). Here, at least a portion of the lead frame 10 may be encapsulated. Next, the encapsulation resin 8 is heated and cured (step S5: fourth process). In particular, the encapsulation resin 8 is precured at 100 degrees C. to 120 degrees C. for 10 minutes to 120 minutes, and then is cured at 175 degrees C. to 185 degrees C. for 1 hour to 2 hours, thereby forming the encapsulation resin 8. In an instance in which the case 7 is included, the method further includes a process of attaching the stacked substrate 5 to the case 7 before the encapsulating process; and after said attaching process, the encapsulation resin 8 is injected into the case 7 and the encapsulation resin 8 is heated and cured. In an instance in which the heat dissipation base 26 is used, the method may include a process of bonding the heat dissipation base 26 to the stacked substrate by the bonding layer 25, more specifically, the heat dissipating base 26 may be bonded to the stacked substrate 5 before the semiconductor chips 1 are bonded to the stacked substrate 5.

As described, according to the semiconductor module of the embodiment, multiple recesses are provided on the bonding portion of the lead frame, whereby thermal stress applied to the top electrode is reduced, deformation of the top electrode may be reduced, and the reliability of the semiconductor module may be enhanced.

Here, examples of the present disclosure are discussed in more detail. However, the present disclosure not limited by the examples below. Table 1 is for an example in which the recesses 23 are provided in only a single row in the lateral direction (y-direction) and dependence of the positions (longitudinal direction) of the recesses 23 is confirmed. Table 2 is for an example in which the number of rows is increased in the longitudinal direction (x-direction) from the base to confirm dependence of the number of the recesses 23. In a comparison example, the lead frame 10 is free of the recesses 23. Adhesion was evaluated by a shear strength test and module reliability was evaluated by a power cycling test. Evaluation values and percentages are shown assuming the comparison example to be “1”.

TABLE 1

| | FIRST | SECOND | THIRD | FOURTH | FIFTH | SIXTH | COMPARISON |
|---|---|---|---|---|---|---|---|
| | EXAMPLE | EXAMPLE | EXAMPLE | EXAMPLE | EXAMPLE | EXAMPLE | EXAMPLE |
| RECESS POSITION | 0.15 | 0.65 | 1.15 | 1.65 | 2.15 | 2.65 | — |
| (POSITION FROM BASE | (5.4□) | (23%) | (41%) | (59%) | (76.8%) | (94.6%) | |
| (mm), PERCENTAGE) | | | | | | | |
| DEFORMATION | 3.5 | 3.9 | 3.55 | 3.2 | 2.7 | 2.4 | 0 |
| REDUCTION RATE (% ) | | | | | | | |
| ADHESION | 25 MPa | ← | ← | ← | ← | ← | 18 MPa |
| | (1.38) | | | | | | (1) |
| RELIABILITY: P/C TEST | 42 | 46 | 42 | 42 | 38 | 35 | 30K cycles |
| (POWER CYCYLING | (1.4) | (1.5) | (1.4) | (1.4) | (1.26) | (1.16) | |
| ENDURANCE) | | | | | | | |

In Table 1, first, second, third, fourth, fifth, and sixth examples are examples in which an entire length of the lead frame 10 is assumed to be 3.8 mm, a length L of the bonding portion 31 is assumed to be 3 mm, a length from a base of the lead frame 10 (hereinafter, may be indicated as “base”) to the center of one of the recesses 23 is assumed to be “D” (refer to FIG. 2), and positions of the recesses 23 from the base are changed. One row of the recesses 23 is formed in which the pore size of each of the recesses 23 is 0.2 mm, the depth thereof is 0.4 mm, and a pitch thereof in the lateral direction is 0.5 mm. In the first example, 5 of the recesses 23 are provided in row R1 while rows R2, R3, R4, F5, and R6 are free of the recesses 23. In the second example, 5 of the recesses 23 are provided in row R2 while rows R1, R3 to R6 are free of the recesses 23. The recesses 23 are similarly provided in the third to sixth examples. The base of the lead frame 10 is a boundary between the bonding portion 31 and the curved portion 32. In Table 1, recess position (position from base (mm), percentage) indicates the length D and the rate D/L (%). A deformation reduction rate (%) indicates a reduction rate relative to the maximum distortion of the top electrode 22 of the comparison example, and is a result of thermal stress analysis by a FEM. In particular, the maximum distortion of the comparison example is used as a reference and the percentage of reduced deformation is regarded as the reduction rate.

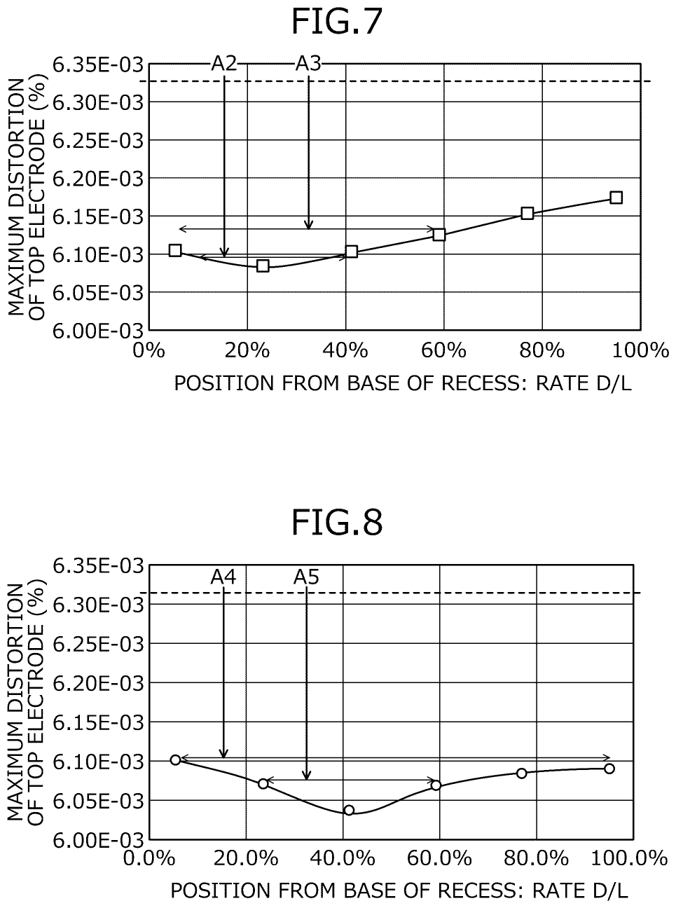

FIG. 7 is a graph depicting a relationship between longitudinal positions where the recesses are provided and deformation of the top electrode of the semiconductor module according to the embodiment. The graph in FIG. 7 is obtained by plotting the results in Table 1. In FIG. 7, a horizontal axis indicates position of the recesses 23 from the base as the rate D/L in units of percent (%). A vertical axis indicates maximum distortion of the top electrode 22 of the semiconductor chips 1 in units of percent (%). In FIG. 7, a dotted line indicates a deformation value of the comparison example that is free of the recesses.

As depicted in Table 1 and FIG. 7, when a single row of the recesses 23 is provided at a position 60% or less from the base of the lead frame 10, the deformation of the top electrode 22 may be reduced 3% or more and the reliability may be enhanced 30% or more (in FIG. 7, A3). In particular, when the recesses 23 are provided at positions 10% to 40% from the base of the lead frame 10 (in FIG. 7, A2), the deformation of the top electrode 22 is reduced 3.5% or more and the reliability is enhanced 40% or more. On the other hand, when the recesses 23 are provided in a range from 60% to the tip, the deformation reduction rate decreases, and the reliability does not improve much.

In other words, it is found that even when the volume percentage of the recesses 23 is the same, the deformation reduction rate varies depending on the position of the recesses 23 and providing the recesses 23 at the base close to the rising portion 33 (the curved portion 32) of the bonding portion 31 is more effective.

TABLE 2

| | SEVENTH | EIGHTH | NINTH | TENTH | ELEVENTH | TWELFTH | COMPARISON |
|---|---|---|---|---|---|---|---|
| | EXAMPLE | EXAMPLE | EXAMPLE | EXAMPLE | EXAMPLE | EXAMPLE | EXAMPLE |
| RECESS POSITION | 0.15 | 0.65 | 1.15 | 1.65 | 2.15 | 2.65 | — |
| (POSITION FROM BASE | (5.4□) | (23%) | (41%) | (59%) | (76.8%) | (94.6%) | |
| (mm), PERCENTAGE) | | | | | | | |
| DEFORMATION | 3.5 | 3.9 | 4.5 | 4.1 | 3.8 | 3.7 | 0 |
| REDUCTION RATE (%) | | | | | | | |
| ADHESION | 25 MPa | 28 MPa | 35 MPa | 39 MPa | 42 MPa | 42 MPa | 18 MPa |
| RELIABILITY: P/C TEST | 42 | 46 | 48 | 46 | 40 | 40 | 30K cycles |
| (POWER CYCYLING | (1.4) | (1.5) | (1.6) | (1.5) | (1.33) | (1.33) | |
| ENDURANCE) | | | | | | | |

In Table 2, seventh, eighth, ninth, tenth, eleventh, and twelfth examples are examples in which the entire length of the lead frame 10 is assumed to be 3.8 mm, the length L of the bonding portion 31 is assumed to be 3 mm, a length from the base of the lead frame 10 to the center of one the recesses 23 is assumed to be “D”, and the number of rows of the recesses 23 is increased from the base. In an instance in which multiple rows of the recesses 23 are provided like in the eighth to twelfth examples, the length D is a length from the base of the lead frame 10 to the center of a farthest one of the recesses 23, said farthest one being farthest from the base of the lead frame 10 among the recesses 23. One row of the recesses 23 is formed so that the pore size of each of the recesses 23 is 0.2 mm, the depth thereof is 0.4 mm, and the pitch thereof in the lateral direction is 0.5 mm. The recess volume percentage of a single row of the recesses 23 is 0.9% (5.4%/6%). In the seventh example, 5 of the recesses 23 are provided in the lateral direction (y-direction) in row R1 while rows R2 to R6 are free of the recesses 23. In the eighth example, 5 of the recesses 23 are provided in the lateral direction (y-direction) in rows R1, R2 while rows R3 to R6 are free of the recesses 23. The recesses 23 are similarly provided in the ninth to twelfth examples. In Table 2, recess position (position from base (mm), percentage) indicates the length D and the rate D/L (%). The deformation reduction rate (%) indicates a reduction rate relative to the maximum distortion of the top electrode 22 of the comparison example, and is a result of thermal stress analysis by a FEM. Adhesion indicates adhesion strength when the recesses 23 of the 5×6 rows in the twelfth example, the recesses 23 of the 5×5 rows in the eleventh example, the recesses 23 of the 5×4 rows in the tenth example, the recesses of the 5×3 rows in the ninth examples, the recesses 23 of the 5×2 rows in the eighth examples, and the recesses 23 of the 5×1 row in the seventh example are provided in a center of a cup (measuring region).

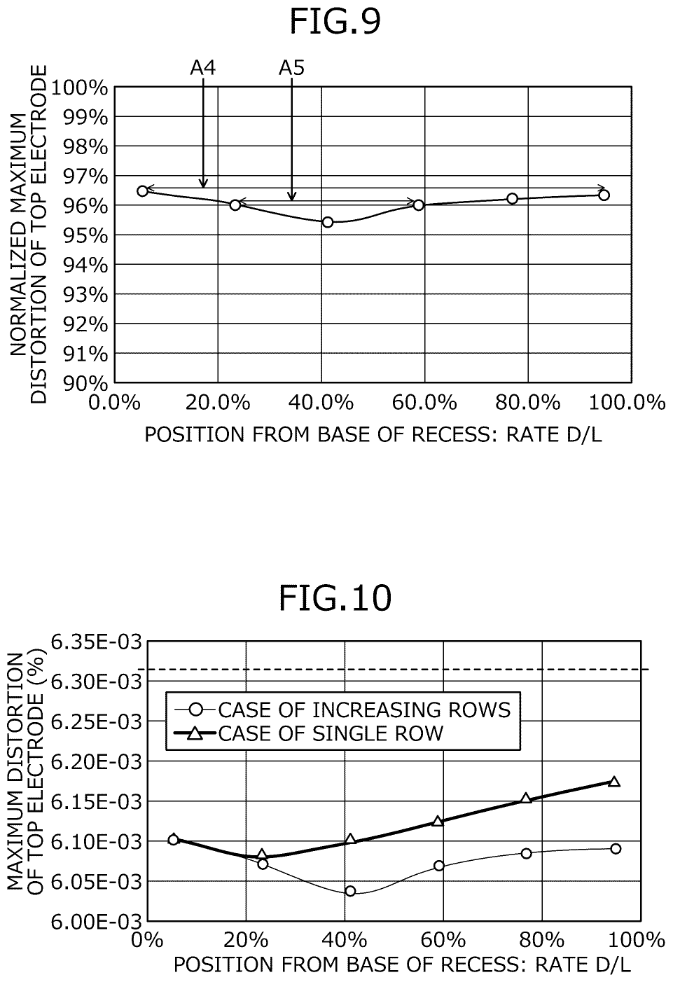

FIGS. 8 and 9 are graphs indicating a relationship between the longitudinal positions where the recesses are provided and deformation of the top electrode of the semiconductor module according to the embodiment. Each of the graphs are obtained by plotting the results in Table 2. In FIG. 8, a horizontal axis indicates positions of the recesses 23 from the base as the rate D/L in units of percent (%). A vertical axis indicates maximum distortion of the top electrode 22 of the semiconductor chips 1 in units of percent (%). In FIG. 8, a dotted line indicates the deformation value of the comparison example that is free of the recesses. In FIG. 9, a horizontal axis indicates position of the recesses 23 from the base as the rate D/L in units of percent (%). A vertical axis indicates the normalized maximum distortion of the top electrode 22 of the semiconductor chips 1 in units of percent (%). In FIG. 9, the comparison example, which is free of the recesses 23 is assumed to be 100%.

As depicted in Table 2 and FIGS. 8 and 9, when the number of rows in which the recesses 23 are provided is increased, from the base of the lead frame 10 to the tip, as compared to when the recesses 23 are provided in only a single row, the deformation of the top electrode 22 is reduced. Furthermore, when the recesses 23 are provided at positions 5% to 90% from the base, the deformation of the top electrode 22 may be reduced 3% or more (in FIG. 9, A4) and the reliability may be enhanced 40% or more. In particular, when the recesses 23 are provided 20% to 60% from the base, the deformation of the top electrode 22 may be enhanced 4% or more (in FIG. 9, A5) and the reliability may be enhanced 50% or more.

Thus, preferably, at least the recesses 23 are provided at positions 20% or less from the base. In other words, in an instance in which the number of rows of the recesses 23 is increased from the base, the recesses 23 are provided from the base close to the rising portion 33 (the curved portion 32) of the bonding portion 31, whereby the deformation may be further reduced.

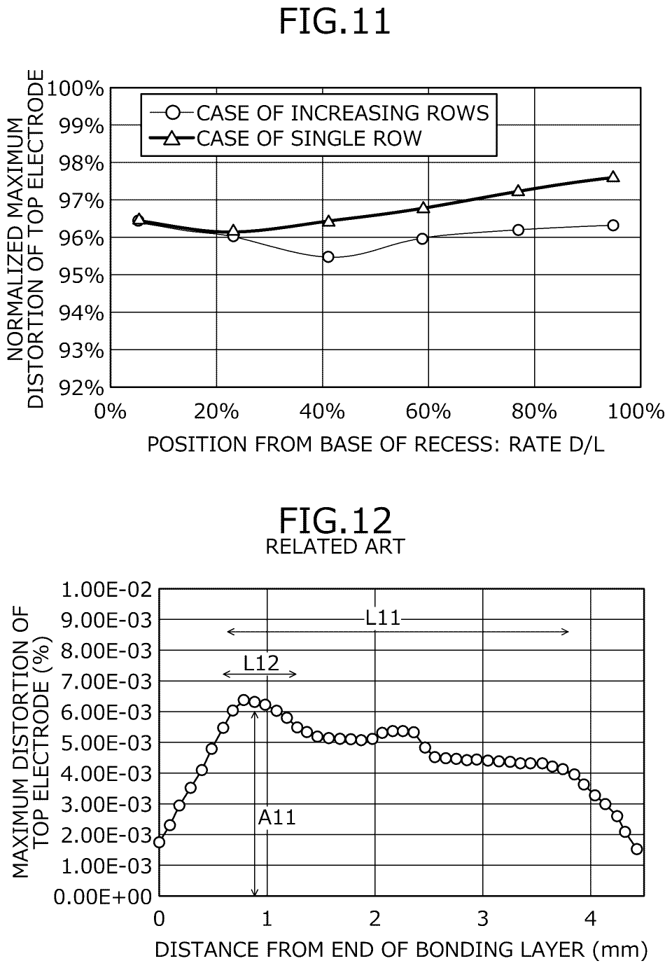

FIGS. 10 and 11 are graphs depicting a relationship between the longitudinal positions where the recesses are provided and deformation of the top electrode of the semiconductor module according to the embodiment. FIGS. 10 and 11 are obtained by plotting the results in Tables 1 and 2. In FIG. 10, a horizontal axis indicates recess position from the base as the rate D/L in units of percent (%). A vertical axis indicates maximum distortion of the top electrode 22 of the semiconductor chips 1 in units of percent (%). In FIG. 10, a dotted line indicates the deformation value of the comparison example, which is free of the recesses, a thick-lined Δ indicates an instance in which only a single row of the recesses 23 is provided while a thin-lined ∘ indicates an instance in which the number of rows of the recesses 23 is increased. Further, in FIG. 11, a horizontal axis indicates recess position from the base as the rate D/L in units of percent (%). A vertical axis indicates the normalized maximum distortion of the top electrode 22 of the semiconductor chips 1 in units of percent (%). In FIG. 11, a thick-lined Δ indicates an instance in which only a single row of the recesses 23 is provided while a thin-lined ∘ indicates an instance in which the number of rows of the recesses 23 is increased. In FIG. 11, the comparison example, which is free of the recesses 23, is assumed to be 100%.

From the results, by providing the recesses 23 in the lead frame 10, the deformation of the top electrode 22 may be reduced and when the number of rows in which the recesses 23 are provided is increased from the base of the lead frame 10 to the tip, the deformation of the top electrode 22 is further reduced, as compared to the instance of only a single row of the recesses 23.

A mechanism of the reduced deformation of the top electrode 22 is presumed to be that formation of the recesses 23 near the base of the lead frame 10 where stress concentrates mitigates the stress due to decreased rigidity of the lead frame 10. Further, it is thought that the encapsulation resin 8 penetrates into the recesses 23 and the encapsulation resin 8 has a lower rigidity than the rigidity of the lead frame 10 and thus, the overall rigidity decreases, facilitating flexibility. Thus, the encapsulation resin 8 of the recesses 23 is presumed to contribute to mitigating stress. It was found that even when the size of the bonding portion 31 of the lead frame 10 and the depth, the pore size, etc. of each of the recesses 23 are changed, effects similar to the examples were obtained.

Here, a shear strength test and a power cycling test performed on the examples are described in detail. The lead frame 10 used in the power cycling test was formed by pressing (laser processing) so that each of the recesses 23 has, in a cross-sectional view, a trapezoidal shape in which the recess portion 23 has a wide opening and a narrow hole tip. Each of the recesses 23 were formed having a pore size of 0.2 mm and a depth of 0.4 mm. An epoxy resin commonly used for encapsulation was used (similarly for the filler).

In the power cycling test, ΔT=35 degrees C., Tjmax=175 degrees C., conditions of energized operation for 1 second and a pause for 9 seconds were set as one cycle, and the number of cycles in which the thermal resistance increased 20% or the electrical resistance of the main current part increased 5% was regarded as the power cycle capacity.

In the shear strength test, the recesses 23 having a predetermined shape (0.2 mm ϕ)/depth 0.4 mm) were provided (pitch in longitudinal direction: 0.5 mm, pitch in lateral direction: 0.46 mm) in a predetermined range on a surface of a 5 mm×5 mm copper plate simulating the bonding portion 31 of the lead frame 10 (pitch in longitudinal direction: 0.5 mm, pitch in lateral direction: 0.46 mm), and this copper plate was used as a substrate for the shear strength test. On the copper plate, an epoxy resin composition that can be used as an encapsulating material was molded having a bottom diameter of 3.6 mm, a top diameter of 3.0 mm, and a height of 3.0 mm, and a thermal curing reaction was carried out at 100 degrees C. to 180 degrees C. for three hours to obtain a test piece of the cured epoxy resin molded onto the copper plate.

A force gauge (load measuring instrument: IMADA ZTA-1000N) was used to measure shear strength. A measurement condition was a velocity of 0.2 mm/s (strain rate), and the strength when the interface between the cured epoxy resin product and the resin composite substrate peeled and broke by pressing the cured epoxy resin portion parallel to the adhesive surface was assumed as the adhesion strength.

In the foregoing, the present disclosure may be variously modified within a range not departing from the spirit of the invention and in the embodiments, for example, dimensions, doping concentrations, etc. of regions may be variously set according to necessary specifications. Further, in the described embodiments, other than silicon, a wide band gap semiconductor such as silicon carbide (SiC), gallium nitride (GaN), or the like is further applicable as a semiconductor.

According to the described disclosure, the recesses are provided in plural on the bonding portion of the lead frame, whereby thermal stress applied to the top electrode is reduced, deformation of the top electrode may be reduced, and the reliability of the semiconductor module may be enhanced.

The semiconductor module and the method of manufacturing a semiconductor module according to the disclosure achieve an effect in that thermal stress applied to an electrode is reduced, deformation of the electrode may be reduced, and reliability may be enhanced.

As described, the semiconductor module and the method of manufacturing a semiconductor module according to the disclosure are useful for power semiconductor modules used in power converting equipment such as inverters, power source devices of various types of industrial machines, igniters of automobiles, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor module, comprising:
a stacked substrate;
a semiconductor device mounted on the stacked substrate;
a lead frame electrically connected to the semiconductor device; and
an encapsulation resin that encapsulates the semiconductor device, the lead frame, and the stacked substrate, wherein
the lead frame has a bonding portion bonded to the semiconductor device, the bonding portion having a plurality of recesses provided thereon.

2. The semiconductor module according to claim 1, wherein each of the plurality of recesses has a pore size in a range of 0.05 mm to 0.4 mm and a depth in a range of 0.1 mm to 0.45 mm.

3. The semiconductor module according to claim 1, wherein a percentage of a total volume of the plurality of recesses relative to a volume of the bonding portion is 5% or more.

4. The semiconductor module according to claim 1, wherein
the lead frame further includes a curved portion that is not bonded to the semiconductor device but connects continuously with the bonding portion, a boundary between the curved portion and the bonding portion being a base of the lead frame, the base extending in a lateral direction of the lead frame;
the plurality of recesses is provided in a single row in the lateral direction of the lead frame; and
each of the plurality of recesses is at a position where a rate D/L is 60% or less, wherein
“L” is a length of the bonding portion in a longitudinal direction of the lead frame, and
“D” is a distance from the base of the lead frame to a center of said each recess in the longitudinal direction of the lead frame.

5. The semiconductor module according to claim 4, wherein said each recess is at a position where the rate D/L is in a range of 10% to 40%.

6. The semiconductor module according to claim 1, wherein
the lead frame further includes a curved portion that is not bonded to the semiconductor device but connects continuously with the bonding portion, a boundary between the curved portion and the bonding portion being a base of the lead frame, the base extending in a lateral direction of the lead frame;
the plurality of recesses is disposed in a plurality of rows each in the lateral direction of the lead frame, each recess being at a position where a rate D/L is in a range of 5% to 60%, wherein
“L” is a length of the bonding portion in a longitudinal direction of the lead frame, and
“D” is a distance from the base of the lead frame to a center of said each recess in the longitudinal direction of the lead frame.

7. The semiconductor module according to claim 6, wherein the rate D/L is in a range of 20% to 60%.

8. A method of manufacturing a semiconductor module, the method comprising:
obtaining a stacked substrate;
bonding a semiconductor device on the stacked substrate;
obtaining a lead frame having a bonding portion, and forming a plurality of recesses in the bonding portion;
bonding the semiconductor device and the bonding portion of the lead frame, with the plurality of recesses formed thereon;
encapsulating the stacked substrate with a resin; and
curing the resin.
